(19) United States
(12) Patent Application Publication
(10) Pub. No.: US 2015/0294843 A1
(43) Pub. Date: Oct. 15, 2015

(54) METHODS FOR EXTENDING CHAMBER COMPONENT LIFE FOR PLASMA PROCESSING SEMICONDUCTOR APPLICATIONS

(71) Applicant: Applied Materials, Inc., Santa Clara, CA (US)

(72) Inventors: Feng CHEN, Santa Clara, CA (US); Benjamin SCHWARZ, San Jose, CA (US); Valentin N. TODOROW, Palo Alto, CA (US); Li ZHANG, Mountain View, CA (US); Tza-Jing GUNG, San Jose, CA (US); Lu LIU, San Jose, CA (US)

(73) Assignee: APPLIED MATERIALS, INC., Santa Clara, CA (US)

(21) Appl. No.: 14/249,042

(22) Filed: Apr. 9, 2014

(51) Int. Cl. H01J 37/32; H01L 21/3065; H01L 21/67

(52) U.S. Cl. CPC H01J 37/32862; H01J 37/32082; H01L 21/67069; H01L 21/3065; H01J 2237/334; H01J 2237/335

(57) ABSTRACT

Embodiments of the present invention generally provide chamber cleaning methods for cleaning a plasma processing chamber with minimum likelihood of erosion occurred on the chamber components so as to extend service life of chamber components for semiconductor plasma applications. In one embodiment, a method of extending chamber component life in a processing chamber includes supplying a cleaning gas mixture into a plasma processing chamber, applying a RF source power to the plasma processing chamber, and applying a voltage to a substrate support assembly disposed in the processing chamber during cleaning.

### BACKGROUND

1. Field

Embodiments of the present invention generally relate to methods of extending the service life of chamber components used in a semiconductor apparatus. More specifically, embodiments of the invention related to methods of extending the service life of chamber components to reduce erosion on the chamber components for semiconductor processing.

2. Description of the Related Art

Integrated circuits have evolved into complex devices that can include millions of transistors, capacitors and resistors on a single chip. The evolution of chip designs continually requires faster circuitry and greater circuit density. The demands for faster circuits with greater circuit densities impose corresponding demands on the materials used to fabricate such integrated circuits. In particular, as the dimensions of integrated circuit components are reduced to the sub-micron scale, it is now necessary to use low resistivity conductive materials (e.g., copper) as well as low dielectric constant insulating materials (dielectric constant less than about 4) to obtain suitable electrical performance from such components.

The demands for greater integrated circuit densities also impose demands on the process sequences used in the manufacture of integrated circuit components. As the geometry limits of the structures used to form semiconductor devices are pushed against technology limits, the need for accurate pattern transfer for the manufacture of structures have small critical dimensions and high aspect ratios has become increasingly difficult. For an interconnection structure, copper is particularly advantageous for use in metal structures due to its desirable electrical properties. Copper interconnects are electrically isolated from each other by an insulating material. When the distance between adjacent metal interconnects and/or thickness of the insulating material has sub-micron dimensions, capacitive coupling may potentially occur between such interconnects. Capacitive coupling between adjacent metal interconnects may cause cross talk and/or resistance-capacitance (RC) delay which degrades the overall performance of the integrated circuit. In order to prevent capacitive coupling between adjacent metal interconnects, low dielectric constant (low k) insulating materials (e.g. dielectric constants less than about 4.0) are needed.

Plasma etching is commonly used in the fabrication of transistors and other electronic devices. During a plasma etch process, a halogen containing gas is often utilized to etch the substrate. After etching, halogen containing residues and etching by-products may periodically build up on the surfaces of the substrate as well as the chamber components of the processing chamber, becoming a source of unwanted particles that may contaminate the substrate and the chamber component. To maintain cleanliness of the processing chamber, a cleaning process is periodically performed after each or a number of substrates are processed in the processing chamber. The cleaning process is used to remove byproduct buildups from the surfaces of the chamber components.

During the cleaning process, similarly, in most cases, aggressive cleaning etchants, such as halogen containing species may be utilized to clean the chamber components. However, aggressive cleaning etchants often undesirably over-attack and erode chamber components, which in turn detrimentally affect the ability to maintain process control during circuit fabrication and adversely deteriorate service life of the chamber components. Eroded chamber components may become yet another source of contaminants that may peel off from the chamber or create flakes during the substrate processing process, resulting in contaminates polluting the processing product substrate and resulting in electronic device failure.

Therefore, there is a need for an improved method for cleaning chamber components as well as removing etching by-products accumulated on the chamber components without adversely damaging or eroding the substrate components so as to maintain chamber components having a reasonable and desirable service life.

### SUMMARY

Embodiments of the present invention generally provide chamber cleaning methods for cleaning a plasma processing chamber with minimum likelihood of erosion occurred on the chamber components so as to extend the service life of chamber components for semiconductor plasma applications. In one embodiment, a method of extending chamber component life in a processing chamber includes supplying a cleaning gas mixture into a plasma processing chamber, applying a RF source power to the plasma processing chamber, and applying a voltage to a substrate support assembly disposed in the processing chamber during cleaning.

In another embodiment, a method of cleaning a processing chamber includes performing a cleaning process in a plasma processing chamber having a substrate absent on a substrate support assembly, the cleaning process includes applying a RF source power to a processing chamber to form a plasma from a cleaning gas mixture supplied to the processing chamber, and applying a voltage to the substrate support assembly while applying the RF source power to the processing chamber.

In yet another embodiment, a method for cleaning a plasma processing chamber includes establishing an electrical potential on a surface of a substrate support assembly disposed in a plasma processing chamber during a chamber cleaning process, wherein the electrical potential is established by applying a voltage greater than 500 Volts to the substrate support assembly during the chamber cleaning process.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic cross-sectional view of an exemplary plasma reactor in which at least one embodiment of the invention may be practiced;

FIG. 2 is a flow diagram of one embodiment of a cleaning process according to one embodiment of the invention; and

FIG. 3 is a schematic cross-sectional view of ions or charges distribution during a plasma cleaning process during the cleaning process of FIG. 2.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

Embodiments of the present invention generally provide chamber cleaning methods for cleaning a plasma processing chamber with minimum likelihood of erosion occurred on the chamber components so as to extend the service life of chamber components for semiconductor plasma applications. In one embodiment, the method includes applying a voltage to a substrate support assembly disposed in a plasma processing chamber during a cleaning process. It is believed that the voltage applied to the substrate support assembly during the cleaning process may efficiently repel ions/charges/radicals away from the substrate support assembly. By doing do, the aggressive etching species may be kept from interacting with the substrate support assembly during the cleaning process, so as to reduce the likelihood of erosion to the substrate support assembly during the cleaning process. It is noted that during the cleaning process, a production substrate or a dummy substrate may be absent from the substrate support assembly.

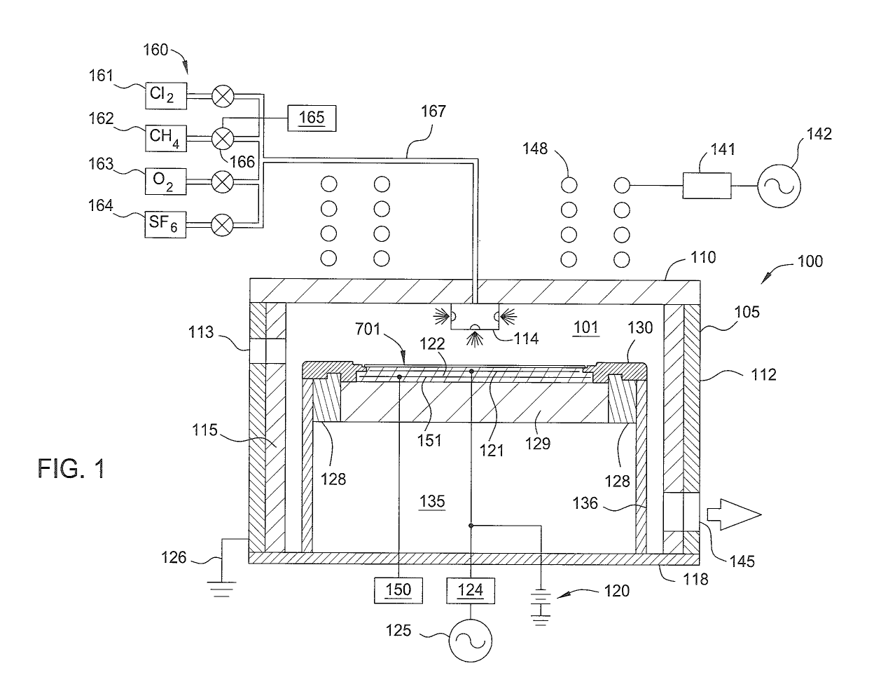

FIG. 1 is a simplified cross-sectional view of an exemplary etching processing chamber 100 for etching a metal layer. The exemplary etching processing chamber 100 is suitable for removing one or more film layers from a substrate and performing a cleaning process in the etching processing chamber after an etching process. One example of the process chamber that may be adapted to benefit from the invention is an AdvantEdge Mesa Etch processing chamber, available from Applied Materials, Inc., located in Santa Clara, Calif. Other suitable examples of the etching processing chamber for performing the invention include Decoupled Plasma Source (DPS), DPS-II, DPS-II AdvantEdge HT, DPS Plus, or DPS DT, Enabler, HART, a HART TS, and other different types of etching processing chambers. It is contemplated that other process chambers, including those available from other manufactures, may be adapted to practice embodiments of the invention.

The etching processing chamber 100 includes a chamber body 105 having a chamber volume 101 defined therein. The chamber body 105 has sidewalls 112 and a bottom 118 which are coupled to ground 126. The sidewalls 112 have a liner 115 to protect the sidewalls 112 and extend the time between maintenance cycles of the etching processing chamber 100. The dimensions of the chamber body 105 and related components of the etching processing chamber 100 are not limited and generally are proportionally larger than the size of a substrate 701 to be processed therein. Examples of substrate sizes include 200 mm diameter, 250 mm diameter, 300 mm diameter and 450 mm diameter, among others.

The chamber body 105 supports a chamber lid assembly 110 to enclose the chamber volume 101. The chamber body 105 may be fabricated from aluminum or other suitable materials. A substrate access port 113 is formed through the sidewall 112 of the chamber body 105, facilitating the transfer of the substrate 701 into and out of the etching processing chamber 100. The access port 113 may be coupled to a transfer chamber and/or other chambers of a substrate processing system (not shown).

A pumping port 145 is formed through the sidewall 112 of the chamber body 105 and connected to the chamber volume 101. A pumping device (not shown) is coupled through the pumping port 145 to the chamber volume 101 to evacuate and control the pressure therein. The pumping device may include one or more pumps and throttle valves.

A gas panel 160 is coupled by a gas line 167 to the chamber body 105 to supply process gases into the chamber volume 101. The gas panel 160 may include one or more process gas sources 161, 162, 163, 164 and may additionally include inert gases, non-reactive gases, and reactive gases, if desired. Examples of process gases that may be provided by the gas panel 160 include, but are not limited to, hydrocarbon containing gas including methane (CH₄), sulfur hexafluoride (SF₆), carbon tetrafluoride (CF₄), hydrogen bromide (HBr), hydrocarbon containing gas, argon gas (Ar), chlorine (Cl₂), nitrogen (N2), and oxygen gas (O₂). Additionally, process gasses may include chlorine, fluorine, oxygen and hydrogen containing gases such as BCl₃, C₄F₈, C₄F₆, CHF₃, CH₂F₂, CH₃F, NF₃, CO₂, SO₂, CO, and H₂ among others.

Valves 166 control the flow of the process gases from the sources 161, 162, 163, 164 from the gas panel 160 and are managed by a controller 165. The flow of the gases supplied to the chamber body 105 from the gas panel 160 may include combinations of the gases.

The lid assembly 110 may include a nozzle 114. The nozzle 114 has one or more ports for introducing the process gases from the sources 161, 162, 164, 163 of the gas panel 160 into the chamber volume 101. After the process gases are introduced into the etching processing chamber 100, the gases are energized to form plasma. An antenna 148, such as one or more inductor coils, may be provided adjacent to the etching processing chamber 100. An antenna power supply 142 may power the antenna 148 through a match circuit 141 to inductively couple energy, such as RF energy, to the process gas to maintain a plasma formed from the process gas in the chamber volume 101 of the etch processing chamber 100. Alternatively, or in addition to the antenna power supply 142, process electrodes below the substrate 701 and/or above the substrate 701 may be used to capacitively couple RF power to the process gases to maintain the plasma within the chamber volume 101. The operation of the power supply 142 may be controlled by a controller, such as controller 165, that also controls the operation of other components in the etching processing chamber 100.

A substrate support assembly 135 is disposed in the chamber volume 101 to support the substrate 701 during processing. The substrate support assembly 135 may include an electro-static chuck 122 for holding the substrate 701 during processing. The electro-static chuck (ESC) 122 uses the electro-static attraction to hold the substrate 701 to the substrate support assembly 135. The ESC 122 is powered by an RF power supply 125 integrated with a match circuit 124. The ESC 122 comprises an electrode 121 embedded within a dielectric body. The RF power supply 125 may provide a RF bias voltage of about 200 volts to about 3000 volts to the electrode 121. The RF power supply 125 may be a DC or pulsed DC source. The RF power supply 125 also includes a system controller for controlling the operation of the electrode 121.

A voltage power generator 120 is coupled to the electrode 121 or other electrode within the substrate support assembly 135. The voltage power generator 120 may facilitate supplying a voltage to the electrode 121. The voltage supplied to the electrode 121 may establish an electrical potential that controls profile and plasma distribution across the surface of the substrate support assembly 135. As ions, charges, radicals and electrons from the plasma during the process may be formed and distributed across the surface of the substrate support assembly 135, by applying a voltage, either positive or negative, to the substrate support assembly 135 is believed to assist efficient control of the distribution or profile of ions, charges, radicals and electrons from the plasma. In one embodiment, the voltage power generator 120 may supply a high voltage power, such as greater than 50 Watts, to the electrode 121 during processing. For example, during a process, particular for a cleaning process, a high voltage power, such as between about 500 Watts and about 5000 Watts, may be supplied to the substrate support assembly 135 as needed.

The ESC 122 may include heaters 151 disposed therein and connected to a power source (not shown), for heating the substrate, while a cooling base 129 supporting the ESC 122 may include conduits for circulating a heat transfer fluid to maintain a temperature of the ESC 122 and substrate 701 disposed thereon. The ESC 122 is configured to perform in the temperature range required by the thermal budget of the device being fabricated on the substrate 701. For example, the ESC 122 may be configured to maintain the substrate 701 at a temperature of about minus about 25 degrees Celsius to about 500 degrees Celsius for certain embodiments.

The cooling base 129 is provided to assist in controlling the temperature of the substrate 701. To mitigate process drift and time, the temperature of the substrate 701 may be maintained substantially constant by the cooling base 129 throughout the time the substrate 701 is in the etch chamber. In one embodiment, the temperature of the substrate 701 is maintained throughout subsequent etch processes at about 70 to 90 degrees Celsius.

A cover ring 130 is disposed on the ESC 122 and along the periphery of the substrate support assembly 135. The cover ring 130 is configured to confine etching gases to a desired portion of the exposed top surface of the substrate 701, while shielding the top surface of the substrate support assembly 135 from the plasma environment inside the etch processing chamber 100. Lift pins (not shown) are selectively moved through the substrate support assembly 135 to lift the substrate 701 above the substrate support assembly 135 to facilitate access to the substrate 701 by a transfer robot (not shown) or other suitable transfer mechanism.

The controller 165 may be utilized to control the process sequence, regulating the gas flows from the gas panel 160 into the etching processing chamber 100 and other process parameters. Software routines, when executed by the CPU, transform the CPU into a specific purpose computer (controller) that controls the etch processing chamber 100 such that the processes are performed in accordance with the present invention. The software routines may also be stored and/or executed by a second controller (not shown) that is collocated with the etching processing chamber 100.

The substrate 701 has various film layers disposed thereon which may include at least one metal layer. The various film layers may require etch recipes which are unique for the different compositions of the other film layers in the substrate 701. Multilevel interconnects that lie at the heart of the VLSI and ULSI technology may require the fabrication of high aspect ratio features, such as vias and other interconnects. Constructing the multilevel interconnects may require one or more etch recipes to form patterns in the various film layers. These recipes may be performed in a single etch processing chamber or across several etch processing chambers. Each etch processing chamber may be configured to etch with one or more of the etch recipes. In one embodiment, etch processing chamber 100 is configured to at least etch a metal layer to form an interconnection structure. For processing parameters provided herein, the etch processing chamber 100 is configured to process a 300 diameter substrate, i.e., a substrate having a plan area of about 0.0707 m². The process parameters, such as flow and power, may generally be scaled proportionally with the change in the chamber volume or substrate plan area.

FIG. 1 only shows one exemplary configuration of various types of plasma reactors that can be used to practice the invention. For example, different types of RF source power and RF bias power can be coupled into the plasma chamber using different coupling mechanisms. Using both the source power and the bias power allows independent control of a plasma density and a bias voltage of the substrate with respect to the plasma. In some applications, the plasma may be generated in a different chamber from the one in which the substrate is located, e.g., remote plasma source, and the plasma subsequently guided into the chamber using techniques known in the art.

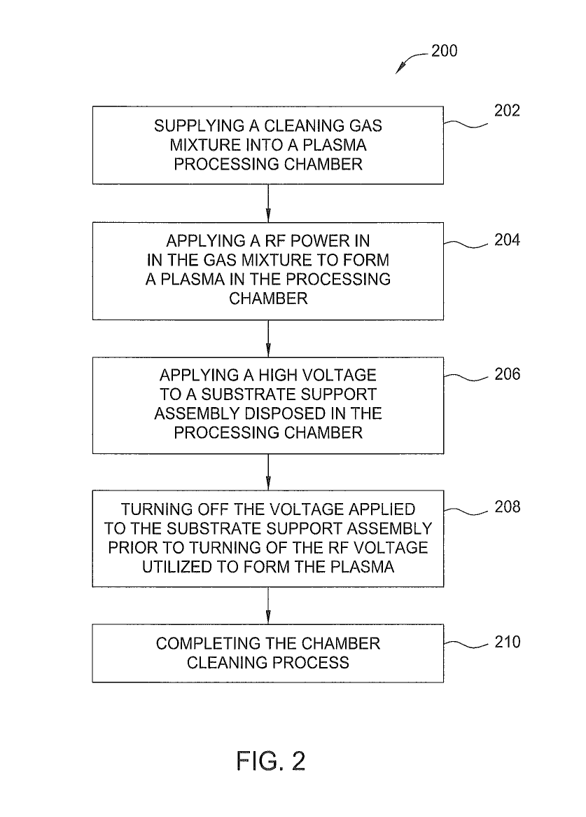

FIG. 2 illustrates a flow diagram of one embodiment of a cleaning process 200 of cleaning a processing chamber, such as the etching processing chamber 100 depicted in FIG. 1, according to one embodiment of the invention. It is noted that the cleaning process 200 as described herein may be practiced in other suitable plasma processing chambers as needed.

Prior to the cleaning process or after the cleaning process, an etching process may be performed in the processing chamber 100. In one embodiment, the substrate may be any substrate or material surface upon which a material layer is formed thereon. The material layer may often be utilized to form a structure, such as a gate structure, an interconnection structure, or a dual damascene structure. The material layer may be a dielectric layer, a metal layer, or any other suitable materials. In one embodiment, the material layer is a metal layer, such as aluminum, aluminum alloy, tantalum, titanium, tungsten, copper, oxides thereof, nitrides thereof, and the like. In an exemplary embodiment, the material layer is TiN. The substrate may include a mask layer utilized as an etch mask to facilitate the fabrication of features or structures in the material layer. In another embodiment, the substrate may have multiple material layers, e.g., a film stack, utilized to form different patterns and/or features, such as interconnection or dual damascene structure and the like. In one embodiment, the material layers disposed on the substrate to be etched may include photoresist layer, hard mask layer, bottom anti-reflective coating (BARC), such as titanium nitride (TiN), tantalum nitride (TaN), tantalum silicon nitride (TaSiN) and metal materials, such as titanium (Ti), tantalum (Ta) aluminum (Al), copper (Cu), and tungsten (W), among others. Suitable examples of hard mask layer include silicon oxynitride (SiON), silicon nitride, TEOS, silicon oxide, amorphous carbon, and silicon carbide.

The substrate may be a material such as crystalline silicon (e.g., Si<100> or Si<111>), silicon oxide, strained silicon, silicon germanium, doped or undoped polysilicon, doped or undoped silicon wafers and patterned or non-patterned wafers silicon on insulator (SOI), carbon doped silicon oxides, silicon nitride, doped silicon, germanium, gallium arsenide, glass, sapphire, metal layers disposed on silicon and the like. The substrate may have various dimensions, such as 200 mm or 300 mm diameter wafers, as well as, rectangular or square panels.

The etching process may utilizes halogen containing gas including at least one of CF₄, C₂F₆, HBr, BCl₃, Cl₂, HCl, C₂H₄, C₃H₆ or C₄H₈ to etch the material layer. After completion of the etching process, the substrate is removed from the substrate support assembly. After the etching process, etching by-products or contaminants may remain in the processing chamber. As such, a cleaning process is performed to clean and remove the etching by-products or contaminants from the processing chamber.

Returning to FIG. 2, the cleaning process 200 begins at a block 202 by supplying a cleaning gas mixture into the processing chamber wherein the substrate which was etched within the processing chamber has been removed from the substrate support assembly (i.e., the substrate is absent from the processing chamber). The cleaning gas mixture may be supplied into the plasma processing chamber to clean the interior of the plasma processing chamber as well as a surface of the substrate support assembly. The cleaning gas mixture includes at least a carbon-fluorine containing gas and an oxygen containing gas. It is believed that the fluorine elements contained in the carbon-fluorine assist removing the metal contaminates, such as Ti containing materials, from the interior of the plasma processing chamber. Optionally, the oxygen containing gas may further assist reaction of the side products produced from the carbon-fluorine gas with the oxygen elements from the oxygen containing gas, forming volatile by products which are readily pumped out of the processing chamber.

In one embodiment, the carbon-fluorine containing gas as used in the cleaning gas mixture may be selected from a group consisting of CF₄, CHF₃, CH₂F₂, C₂F₆, C₂F₈, SF₆, NF₃ and the like. The optional oxygen containing gas may be selected from a group consisting of O₂, N₂O, NO₂, O₃, CO, CO₂ and the like. In one example, the carbon-fluorine containing gas supplied in the cleaning gas mixture is CF₄ and the oxygen containing gas supplied in the cleaning gas mixture is O₂.

At block 204, after the cleaning gas mixture is supplied in the processing chamber, an RF source power is applied to the plasma processing chamber to form a plasma in the cleaning gas mixture. The RF source power may be applied to the processing chamber to ignite the plasma in the cleaning gas mixture. A RF bias power may also be utilized to form a cleaning plasma in the cleaning gas mixture as necessary.

The RF source power as applied in the cleaning gas mixture may have having a RF frequency of between about 2 MHz and about 180 MHz. In one embodiment, the RF source power applied to the cleaning gas mixture may dissociate the cleaning gas into ions, charges, electrons, and other charged or neutral species. The ions, charges, electrons, and other charged or neutral species formed in the plasma may provide an isotropic etching process that facilitates cleaning an interior surface of the processing chamber. During etching when the RF source power is on, ions, radicals, or active species may be uniformly distributed in the plasma, gradually flow to an interior surface of the processing chamber without specific directionality, performing an isotropic etching process, e.g., with non-directional ions, to remove residuals from the processing chamber. As the ions, radicals, or active species generated by the isotropic etching process have no specific directionality, the reactive ions may scatter radially and symmetrically to chemically react with most of the interior surface of the processing chamber exposed to the plasma, including the surface of the substrate support assembly used to support the substrate during processing. In some embodiment, excess exposure of the substrate support assembly to the aggressive active species from the plasma may adversely erode and damage the surface of the substrate support assembly.

Furthermore, in some embodiments, a bias RF power may also be applied to produce plasma in the cleaning gas mixture. The bias RF power may assist producing anisotropic cleaning process during the overall cleaning process. When the RF bias power is on, ions, radicals, or active species generated in the plasma become directional and may be accelerated toward the surface of the substrate support assembly, performing an anisotropic cleaning process, e.g., with directional ions, radicals, or active species generated in the plasma, to cleaning the interior surface of the processing chamber along with the surface of the substrate support assembly.

While applying the RF source power, along with optional RF bias power, several process parameters may be controlled. In one embodiment, the RF source power may be supplied to the processing chamber between about 100 Watt and about 10000 Watt, such as about 1500 Watts. The pressure of the processing chamber may be controlled at between about 1 milliTorr and about 100 milliTorr, such as between about 5 milliTorr and about 15 milliTorr, for example about 10 milliTorr. A carbon-fluorine containing gas is utilized to be supplied in the cleaning gas mixture at a flow rate between about 0 sccm and about 300 sccm, for example about 50 sccm. A chlorine containing gas is utilized to be supplied in the cleaning gas mixture at a flow rate between about 0 sccm and about 400 sccm, for example about 300 sccm The optional oxygen containing gas supplied in the cleaning gas mixture may be supplied into the processing chamber at a flow rate between about 0 sccm to about 1500 sccm, for example about 1000 sccm. In one embodiment, the carbon fluorine containing gas and the oxygen containing gas supplied in the first cleaning gas mixture is supplied at a ratio between about 10:1 to about 1:10, such as between about 1:1 and about 1:2. The cleaning process may be performed between about 0 seconds and about 180 seconds.

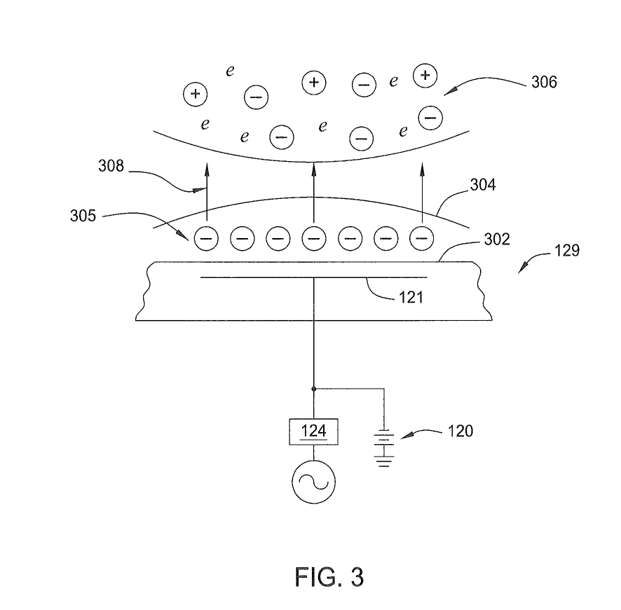

At block 206, while applying the RF source power, or optional the RF bias power, to the cleaning gas mixture, a high voltage, such as a voltage greater than 500 Volts, either positive or negative, may be applied to the substrate support assembly from the voltage power generator 120 depicted in FIG. 1. The voltage applied to the substrate support assembly may create an electrical potential around the surface of the substrate support assembly to the plasma, which repels ions from the plasma coming close to the surface of the substrate support assembly using electrostatic force, thus efficiently reducing likelihood of damage or erosion to the substrate support assembly. As shown in FIG. 3, the plasma may be dissociated to include ions, radicals, charges, electrons or active species 306. The voltage applied from the voltage power generator 120 may create an electrical positional 304 which repels ions, radicals, electrons or active species 306 in the plasma, effectively pushing them away from the surface 302 of the substrate support assembly 135, preventing the surface 302 of the substrate support assembly 135 from being attacked during the cleaning process. Thus, by applying an appropriate power level to establish an electric field between the surface 302 of the substrate support assembly 135 and the plasma as generated in the processing chamber, an electric potential as obtained may efficiently minimize damage and erosion from the surface 302 of the substrate support assembly 135, so as to efficiently enhance surface lifetime of the chamber components, such as the substrate support assembly 135 disposed in the processing chamber.

In one embodiment, during cleaning with the RF source power and/or with the optional RF bias power provided to the processing chamber, a voltage may be applied to the electrode 121 disposed in the substrate support assembly 135, establishing an electric field and creating an electric potential, which may repel, e.g., push away, ions, radicals, electrons or active species 306 in the plasma away from the surface 302 of the substrate support assembly 135. The applied voltage may be greater than 500 Volts, for example between about 500 Volts and about 5000 Volts. The electrode 121 having the voltage applied thereon then generates an electrical potential to repel ions, radicals, electrons or active species 306 away from the surface 302 of the substrate support assembly 135. Furthermore, the voltage as applied to the surface 302 may create charges 305 or electrons with similar polarity to ions, radicals, electrons or active species 306 so as to repel them, as shown by arrow 308, away from the surface 302 of the substrate support assembly 135.

During cleaning, the ions, radicals, electrons or active species 306 are efficiently repelled and kept away from the substrate support assembly when sufficient voltage is applied to the substrate support assembly. In one embodiment, the voltage as applied to the substrate support assembly may be a positive voltage, a negative voltage, or alternate pulses of positive and negative voltages as needed. In one embodiment, the negative voltage is applied to the substrate support assembly. The voltage as supplied may be greater than at least 500 Volts and up to 5000 Volts, such as between about 1000 Volts and 5000 volts, for example about 2000 Volts and about 4000 Volts, may be applied to the substrate support assembly. However, the voltage as applied to the substrate support is controlled under the break-down voltage of the material utilized to fabricate the substrate support assembly.

At block 208, after the cleaning process has substantially removed the residuals and etching by-products from the interior surfaces of the processing chamber, the voltage supplied to the substrate support assembly may then be terminated prior to the termination of the RF source power and/or the optional RF bias power applied to the processing chamber to generate the plasma during the cleaning process. By terminating the voltage supplied to the substrate support assembly earlier than the RF source power and/or the RF bias power applied to the processing chamber, it is believed that surface charges accumulated on the surface of the substrate support assembly may be released prior to extinguishing the plasma. By doing so, charges remaining on the substrate support assembly surface may be eliminated, reducing the likelihood of substrate warpage or substrate sticking, which may adversely resulting in substrate scratch during substrate transfer or during later processing within the processing chamber.

At block 210, after the voltage applied to the substrate support assembly is terminated as well as termination of the RF source power and/or the optional RF bias power, the cleaning process is then completed and the chamber is ready to perform a substrate process, such as an etching process, deposition process, or any suitable process performed on a production substrate, or any suitable substrates as needed.

It is contemplated that the process 200 as described above may be adapted to benefit maintaining chamber cleanliness for processes other than removing etching by-products. Suitable examples of other processes include CVD, PVD, ALD, ion implantation, ashing, nitration or other suitable plasma or non-plasma semiconductor fabrication process or other process wherein the process is performed by applying a voltage to the substrate support assembly during a plasma cleaning process so as to create a electrical potential that repeals ions, charges, electrons, radicals away from the substrate support assembly, so as to efficient reduce damage and erosion to the substrate support assembly and promotes and increase service lift of the chamber components.

Thus, the present application provides methods for extending the service life of chamber components for semiconductor or other processing. The methods is performed by applying a voltage to the substrate support assembly during a plasma cleaning process so as to create a electrical potential that repeals ions, charges, electrons, radicals away from the substrate support assembly. The methods advantageously reduces likelihood of erosion to chamber components, to minimize damage to the substrate support assembly and processing chamber and, thus, promoting service life of chamber components.

While the foregoing is directed to embodiments of the present invention, other and further embodiments of the invention may be devised without departing from the basic scope thereof, and the scope thereof is determined by the claims that follow.

1. A method of extending chamber component life in a processing chamber, comprising:
supplying a cleaning gas mixture into a plasma processing chamber;
applying a RF source power to the plasma processing chamber; and
applying a voltage to a substrate support assembly disposed in the processing chamber during cleaning.

2. The method of claim 1, wherein applying the voltage to the substrate support assembly further comprises:
applying a negative voltage to the substrate support assembly.

3. The method of claim 1, wherein applying the voltage to the substrate support assembly further comprises:
supplying greater than 500 Volts to the substrate support assembly.

4. The method of claim 1, wherein applying the voltage to the substrate support assembly further comprises:
supplying at between about 2000 Volts and about 3000 Volts to the substrate support assembly.

5. The method of claim 1, wherein the cleaning gas mixture is supplied in absence of a substrate disposed on the substrate support assembly.

6. The method of claim 1, further comprising:
performing an etching process prior to supplying the cleaning gas mixture into the processing chamber.

7. The method of claim 1, wherein applying the RF source power to the processing chamber further comprises:
applying a RF bias power to the processing chamber.

8. The method of claim 1, wherein applying the voltage to the substrate support assembly further comprises:
applying the voltage to the substrate support assembly in a pulsed mode.

9. The method of claim 8, further comprising:
switching the voltage applied to the substrate support assembly with different polarity.

10. The method of claim 1, further comprising:
terminating the voltage applied to the substrate support assembly; and
terminating the RF source power applied to the processing chamber after the voltage applied to the substrate support assembly is terminated.

11. The method of claim 10, further comprising:
performing an etching process after a cleaning process is competed in the processing chamber.

12. A method of cleaning a processing chamber, comprising:
performing a cleaning process in a plasma processing chamber having a substrate absent on a substrate support assembly, the cleaning process comprising:
applying a RF source power to a processing chamber to form a plasma from a cleaning gas mixture supplied to the processing chamber; and
applying a voltage to the substrate support assembly while applying the RF source power to the processing chamber.

13. The method of claim 12, wherein applying the voltage to the substrate support assembly further comprises:
establishing an electrical potential on a surface of the substrate support assembly against the plasma generated in the processing chamber.

14. The method of claim 13, wherein establishing the electrical potential further comprises:
applying the voltage to the substrate support assembly in a pulsed mode.

15. The method of claim 12, wherein applying the voltage to the substrate support assembly further comprises:
applying a negative voltage between about 2000 Volts and about 3000 Volts to the substrate support assembly.

16. The method of claim 12, further comprising:
terminating the voltage applied to the substrate support assembly; and
terminating the RF source power applied to the processing chamber after the voltage applied to the substrate support assembly is terminated.

17. The method of claim 12, further comprising:
removing charges accumulated on the surface of the substrate support assembly prior to terminating the RF source power applied to the processing chamber.

18. A method for cleaning a plasma processing chamber comprising:
establishing an electrical potential on a surface of a substrate support assembly disposed in a plasma processing chamber during a chamber cleaning process, wherein the electrical potential is established by applying a voltage greater than 500 Volts to the substrate support assembly during the chamber cleaning process.

19. The method of claim 18, further comprising:
applying a RF source power to form a plasma within the plasma processing chamber while establishing the electrical potential on the surface of the substrate support assembly.

20. The method of claim 18, further comprising:
terminating the electrical potential established on the surface of the substrate support assembly prior to completion of the cleaning process.
